(19) United States
(12) Patent Application Publication
(10) Pub. No.: US 2017/0022601 A1
(43) Pub. Date: Jan. 26, 2017

(54) A PROCESSING APPARATUS FOR PROCESSING DEVICES, PARTICULARLY DEVICES INCLUDING ORGANIC MATERIALS THEREIN, AND METHOD FOR TRANSFERRING AN EVAPORATION SOURCE FROM A PROCESSING VACUUM CHAMBER TO A MAINTENANCE VACUUM CHAMBER OR FROM THE MAINTENANCE VACUUM CHAMBER TO THE PROCESSING VACUUM CHAMBER

(71) Applicants: Jose Manuel DIEGUEZ-CAMPO, Hanau (DE); Stefan BANGERT, Steinau (DE); Uwe SCHÜßLER, Aschaffenburg (DE); Dieter HAAS, San Jose, CA (US); Applied Materials, Inc., Santa Clara, CA (US)

(72) Inventors: Jose Manuel DIEGUEZ-CAMPO, Hanau (DE); Stefan BANGERT, Steinau (DE); Uwe SCHÜßLER, Aschaffenburg (DE); Dieter HAAS, San Jose, CA (US)

(21) Appl. No.: 15/039,397

(22) PCT Filed: Aug. 19, 2014
(86) PCT No.: PCT/EP2014/067673

§ 371 Date: May 25, 2016

(30) Foreign Application Priority Data
Dec. 10, 2013 (EP) PCT/EP2013/076120

(51) Int. Cl. C23C 14/24; C23C 14/12; H01L 51/56; C23C 14/04

(52) U.S. Cl. CPC C23C 14/243; C23C 14/042; C23C 14/12; C23C 14/246; H01L 51/56; H01L 51/001

(57) ABSTRACT

A processing apparatus for processing devices, particularly devices including organic materials therein, is described. The processing apparatus includes a processing vacuum chamber; at least one evaporation source for organic material, wherein the at least one evaporation source includes at least one evaporation crucible, wherein the at least one evaporation crucible is configured to evaporate the organic material, and at least one distribution pipe with one or more outlets, wherein the at least one distribution pipe is in fluid communication with the at least one evaporation crucible; and a maintenance vacuum chamber connected with the processing vacuum chamber, wherein the at least one evaporation source can be transferred from the processing vacuum chamber to the maintenance vacuum chamber and from the maintenance vacuum chamber to the processing vacuum chamber.

### TECHNICAL FIELD

Embodiments of the present disclosure relate to a processing apparatus for processing devices, particularly devices including organic materials therein, and relate to a method for transferring an evaporation source from a processing vacuum chamber to a maintenance vacuum chamber or from the maintenance vacuum chamber to the processing vacuum chamber.

### BACKGROUND

Organic evaporators are tools for the production of organic light-emitting diodes (OLED). OLEDs are light-emitting diodes, in which the emissive layer includes a thin-film of certain organic compounds. OLEDs are used in the manufacture of television screens, computer monitors, mobile phones, other hand-held devices, etc., for displaying information. OLEDs can also be used for general space illumination. The range of colors, brightness, and viewing angle possible with OLED displays are greater than that of traditional LCD displays because OLED pixels directly emit light and do not require a back light. The energy consumption of OLED displays is considerably less than that of traditional LCD displays. Further, OLEDs can be manufactured onto flexible substrates, resulting in further applications. An OLED display, for example, may include layers of organic material situated between two electrodes that are deposited on a substrate in a manner to form a matrix display panel having individually energizable pixels. The OLED can be placed between two glass panels, and the edges of the glass panels are sealed to encapsulate the OLED therein.

There are challenges encountered in the manufacture of OLED display devices. In one example, there are several labor-intensive steps necessary to encapsulate the OLED between the two glass panels to prevent possible contamination of the device. In another example, different sizes of display screens and glass panels may require substantial reconfiguration of the process and process hardware used to form the display devices. Generally, there is a desire to manufacture OLED devices on large area substrates.

OLED displays or OLED lighting applications include a stack of several organic materials, which are for example evaporated in a vacuum chamber of a processing apparatus. The organic materials are deposited on a substrate in a subsequent manner through shadow masks using evaporation sources. The substrate, the shadow masks and the evaporation sources are provided within the vacuum chamber. The evaporation sources have to be serviced and refilled from time to time. For servicing and refilling evaporation sources, the processing apparatus has to be shut down, the vacuum chamber has to be vented, and the evaporation source has to be removed from the vacuum chamber. In view of this, servicing and refilling evaporation sources causes considerable workload and is time consuming, leading to an increased downtime of the processing apparatus and a reduced processing efficiency or throughput.

Therefore, there is a need for processing apparatuses for processing devices, particularly devices including organic materials therein, and methods for transferring an evaporation source, which facilitate servicing and refilling of evaporations sources, and reduce a downtime of the processing apparatus.

### SUMMARY OF THE DISCLOSURE

In light of the above, a processing apparatus for processing devices, particularly devices including organic materials therein, and a method for transferring an evaporation source from a processing vacuum chamber to a maintenance vacuum chamber or from the maintenance vacuum chamber to the processing vacuum chamber are provided. Further aspects, benefits, and features of the present disclosure are apparent from the claims, the description, and the accompanying drawings.

According to an aspect of the present disclosure, a processing apparatus for processing devices, particularly devices including organic materials therein, is provided. The processing apparatus includes a processing vacuum chamber; at least one evaporation source for a material, wherein the at least one evaporation source includes at least one evaporation crucible, wherein the at least one evaporation crucible is configured to evaporate the material, and at least one distribution pipe with one or more outlets, wherein the at least one distribution pipe is in fluid communication with the at least one evaporation crucible; and a maintenance vacuum chamber connected with the processing vacuum chamber, wherein the at least one evaporation source can be transferred from the processing vacuum chamber to the maintenance vacuum chamber and from the maintenance vacuum chamber to the processing vacuum chamber.

According to another aspect of the present disclosure, a processing apparatus for processing devices, particularly devices including organic materials therein, is provided. The processing apparatus includes a processing vacuum chamber; at least one evaporation source for a material, wherein the at least one evaporation source includes at least one evaporation crucible, wherein the at least one evaporation crucible is configured to evaporate the material, and at least one distribution pipe with one or more outlets, wherein the at least one distribution pipe is in fluid communication with the at least one evaporation crucible; and a maintenance vacuum chamber connected with the processing vacuum chamber, wherein the at least one evaporation source can be transferred from the processing vacuum chamber to the maintenance vacuum chamber and from the maintenance vacuum chamber to the processing vacuum chamber, wherein the connection of the maintenance vacuum chamber and the processing vacuum chamber includes an opening, wherein the opening is configured for the transfer of the at least one evaporation source from the processing vacuum chamber to the maintenance vacuum chamber and from the maintenance vacuum chamber to the processing vacuum chamber, wherein the processing apparatus further includes a sealing device configured for closing the opening, and wherein the sealing device is attached to the at least one evaporation source.

According to still another aspect of the present disclosure, a method for transferring an evaporation source from a processing vacuum chamber to a maintenance vacuum chamber or from the maintenance vacuum chamber to the processing vacuum chamber is provided. The method includes moving an evaporation crucible and a distribution pipe of the evaporation source from the processing vacuum chamber to the maintenance vacuum chamber or from the maintenance vacuum chamber to the processing vacuum chamber through an opening provided between the processing vacuum chamber and the maintenance vacuum chamber.

Embodiments are also directed at apparatuses for carrying out the disclosed methods and include apparatus parts for performing each described method aspects. These method aspects may be performed by way of hardware components, a computer programmed by appropriate software, by any combination of the two or in any other manner. Furthermore, embodiments according to the disclosure are also directed at methods for operating the described apparatus. It includes method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1A to 1C show schematic top views of a processing apparatus for processing devices, particularly devices including organic materials therein, according to embodiments described herein;

FIG. 2 shows a schematic top view of a processing apparatus for processing devices, particularly devices including organic materials therein, according to further embodiments described herein;

FIGS. 3A and 3B show schematic top views of a processing apparatus for processing devices, particularly devices including organic materials therein, according to still further embodiments described herein;

FIGS. 4A to 4C show schematic top views of a processing apparatus for processing devices, particularly devices including organic materials therein, according to yet further embodiments described herein;

FIG. 5 shows a schematic perspective view of a processing apparatus for processing devices, particularly devices including organic materials therein, according to embodiments described herein;

FIGS. 6A to 6C show schematic views of portions of an evaporation source of a processing apparatus according to embodiments described herein; and

FIG. 7 shows a flowchart of a method for transferring an evaporation source from a processing vacuum chamber to a maintenance vacuum chamber or from the maintenance vacuum chamber to the processing vacuum chamber according to embodiments described herein.

### DETAILED DESCRIPTION OF EMBODIMENTS

Reference will now be made in detail to the various embodiments of the disclosure, one or more examples of which are illustrated in the Figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

FIGS. 1A to 1C show schematic top views of a processing apparatus 100 for processing devices, particularly devices including organic materials therein, according to embodiments described herein.

According to an aspect of the present disclosure, the processing apparatus 100 for processing devices, particularly devices including organic materials therein, includes a processing vacuum chamber 110; an evaporation source 1000 for organic material, wherein the evaporation source 1000 includes an evaporation crucible 1004, wherein the evaporation crucible 1004 is configured to evaporate the organic material, and a distribution pipe 1006 with one or more outlets, wherein the distribution pipe 1006 is in fluid communication with the evaporation crucible 1004; and a maintenance vacuum chamber 150 connected with the processing vacuum chamber 110, wherein the evaporation source 1000 can be transferred from the processing vacuum chamber 110 to the maintenance vacuum chamber 150 and from the maintenance vacuum chamber 150 to the processing vacuum chamber 110. In some implementations, the distribution pipe 1006 is rotatable around an axis during evaporation.

The processing apparatus according to the embodiments disclosed herein facilitates servicing and/or refilling of evaporation source 1000, and can reduce a downtime of the processing apparatus. By attaching the maintenance vacuum chamber 150, which can be vented independently from the processing vacuum chamber 110, to the processing vacuum chamber 110, it is possible to exchange the evaporation source 1000, e.g. after it is exhausted, and service it in the maintenance vacuum chamber 150 without venting the vacuum system and/or without stopping production.

FIGS. 1A to 1C show the processing apparatus 100 with the evaporation source 1000 being at different positions. In FIGS. 1A and 1B, the evaporation source 1000 is positioned in the processing vacuum chamber 110, and in FIG. 1C the evaporation source 1000 is positioned in the maintenance vacuum chamber 150, e.g., for servicing and/or refilling. Although FIGS. 1A to 1C illustrate one evaporation source 1000, in some examples two or more evaporation sources 1000 can be provided in the processing apparatus 100. As an example, a first evaporation source can be positioned in the processing vacuum chamber 110, and a second evaporation source can be positioned in the maintenance vacuum chamber 150. The first evaporation source can be operated for manufacturing devices, particularly devices including organic materials therein, while the second evaporation source positioned in the maintenance vacuum chamber 150 can be simultaneously serviced and/or refilled, and a downtime of the processing apparatus can be further reduced or even avoided.

According to some embodiments, which can be combined with other embodiments described herein, the processing apparatus 100 includes a transfer device (not shown) configured for transferring the evaporation source 1000 from the processing vacuum chamber 110 to the maintenance vacuum chamber 150 and from the maintenance vacuum chamber 150 to the processing vacuum chamber 110. The transfer device can include a displacement device, such as an actuator, a drive, or an arm, connectable to the evaporation source 1000 for performing the transfer.

The evaporation source 1000 has one or more evaporation crucibles 1004 adapted to contain the evaporation material, and has one or more distribution pipes 1006. According to some embodiments, which can be combined with other embodiments described herein, the processing apparatus 100, and particularly the evaporation source 1000, includes a support 1002 for the distribution pipe 1006. The distribution pipe 1006 is supported by the support 1002. Further, according to some embodiments, the evaporation crucibles 1004 can also be supported by the support 1002. In some implementations, the evaporation source 1000 is configured for a rotation around an axis, particularly during evaporation. Various applications for OLED device manufacturing include processes, where two or more organic materials are evaporated simultaneously. In some embodiments, two or more distribution pipes and corresponding evaporation crucibles can be provided next to each other. Such an evaporation source may also be referred to as an evaporation source array, e.g. wherein more than one kind of organic material is evaporated at the same time. An example of an evaporation source 1000 is described with reference to FIGS. 6A to C.

In some implementations, the distribution pipe 1006 is a vapor distribution showerhead, particularly a linear vapor distribution showerhead. The distribution pipe 1006 may provide a line source extending substantially vertically. According to embodiments, which can be combined with other embodiments described herein, substantially vertically is understood particularly when referring to the substrate orientation, to allow for a deviation from the vertical direction of 20° or below, e.g. of 10° or below. This deviation can be provided for example because a substrate support with some deviation from the vertical orientation might result in a more stable substrate position. Yet, the substrate orientation during deposition of the organic material is considered substantially vertical, which is considered different from the horizontal substrate orientation.

In some embodiments, a surface of the substrates 121 is coated by the evaporation source 1000 extending in one direction corresponding to one substrate dimension and a translational movement along the other direction corresponding to the other substrate dimension. Vapor generated in the evaporation crucible 1004 can move upwardly and out of one or more outlets (not shown) of the distribution pipe 1006. The one or more outlets of the distribution pipe 1006 can be one or more openings or one or more nozzles, which can, e.g., be provided in a showerhead or another vapor distribution system. The evaporation source 1000 can include a vapor distribution showerhead, e.g. a linear vapor distribution showerhead having a plurality of nozzles or openings. A showerhead as understood herein can include an enclosure having openings such that the pressure in the showerhead is higher than that outside of the showerhead, for example by at least one order of magnitude.

According to some embodiments, which can be combined with other embodiments described herein, the distribution pipe 1006 can be designed in a triangular shape, so that the openings or the nozzle arrays can be positioned as close as possible to each other. This allows for achieving an improved mixture of different organic materials, e.g. for the case of the co-evaporation of two, three or even more different organic materials.

According to embodiments described herein, which can be combined with other embodiments described herein, the rotation of the distribution pipe 1006 can be provided by a rotation of an evaporator control housing, on which at least the distribution pipe 1006 is mounted. Additionally or alternatively, the rotation of the distribution pipe 1006 can be provided by moving the evaporation source 1000 along a curved portion off a looped track. As an example, the evaporation crucible 1004 is mounted on the evaporator control housing, and the evaporation source 1000 can include the distribution pipe 1006 and the evaporation crucible 1004, which may both, i.e. together, be rotatably mounted.

In some implementations, a mask 132 for masking of the layer deposition on the substrate 121 can be provided between the substrate 121 and the evaporation source 1000. Organic material is evaporated from the distribution pipe 1006 and deposited on the substrate 121 through the mask 132. According to some embodiments, the mask 132, i.e. a first mask corresponding to a first substrate of the two substrates 121 shown in FIGS. 1A to C and a second mask corresponding to a second substrate of the two substrates 121, are provided in a mask frame 131 to hold the mask 132 in a predetermined position.

According to yet further embodiments, which can additionally or alternatively be implemented, the evaporation source 1000 described herein allows for temperature variation at the position of the mask 132, which can be, for example, below 5 Kelvin, or even below 1 K. The reduction of the heat transfer from the evaporation source 1000 to the mask 132 can be provided by an improved cooling. Additionally or alternatively, e.g., when the distribution pipe 1006 has the triangular shape, the area, which radiates towards the mask 132, is reduced. Additionally, a stack of metal plates, for example up to 10 metal plates, can be provided to reduce the heat transfer from the evaporation source 1000 to the mask 132. According to some embodiments, which can be combined with other embodiments described herein, the heat shields or metal plates can be provided with orifices for the outlets or nozzles and may be attached to at least the front side of the evaporation source 1000, i.e. the side facing the substrate 121.

According to some embodiments, which can be combined with other embodiments described herein, the evaporation source 1000 is configured for the translational movement, in particular within the processing vacuum chamber 110. As an example, the processing apparatus 100 includes a first drive configured for the translational movement of the evaporation source 1000. In some embodiments, the first drive is connectable to the evaporation source 1000 or is included in the evaporation source 1000. According to some embodiments, the support 1002 is connectable to the first drive or includes the first drive. The first drive can be a motor or another suitable actuator.

According to some embodiments, which can be combined with other embodiments described herein, the processing apparatus 100 further includes an evaporation source support system disposed in the processing vacuum chamber 110 and having at least two tracks 220, wherein the at least two tracks 220 of the evaporation source support system are configured for the translational movement of the evaporation source 1000 at least within the processing vacuum chamber 110. As an example, the first drive can be configured to move or transfer the evaporation source 1000 along the at least two tracks 220.

In some implementations, the evaporation source 1000 is provided in the processing vacuum chamber 110 on the at least two tracks 220, e.g. a looped track or linear guide. The at least two tracks 220 are configured for the translational movement of the evaporation source 1000, in particular during operation, such as a deposition process. According to some embodiments, which can be combined with other embodiments described herein, the first drive for the translational movement of the evaporation source 1000 can be provided at the least two tracks 220, in the evaporation source 1000, within the processing vacuum chamber 110, or a combination thereof.

According to some embodiments, which can be combined with other embodiments described herein, the processing apparatus 100 further includes another vacuum chamber 106 connected to the processing vacuum chamber 110 via a valve 105, wherein the other vacuum chamber 106 can, for example, be configured for a transport of the substrate 121 into the processing vacuum chamber 110 and out of the processing vacuum chamber 110. FIGS. 1A to 1C show the valve 105, for example a gate valve. The valve 105 allows for a vacuum seal between the processing vacuum chamber 110 and the other vacuum chamber 106. The valve 105 can be opened for transport of the substrate 121 and/or the mask 132 into the processing vacuum chamber 110 or out of the processing vacuum chamber 110.

In some implementations, the maintenance vacuum chamber 150 is provided adjacent to the processing vacuum chamber 110, and the maintenance vacuum chamber 150 and the processing vacuum chamber 110 are connected. According to some embodiments, which can be combined with other embodiments described herein, the connection of the maintenance vacuum chamber 150 and the processing vacuum chamber 110 includes an opening 152, wherein the opening 152 is configured for the transfer of the evaporation source 1000 from the processing vacuum chamber 110 to the maintenance vacuum chamber 150 and from the maintenance vacuum chamber 150 to the processing vacuum chamber 110. In some embodiments, the processing apparatus 100 further includes a sealing device (not shown) configured for closing the opening 152. In particular, the sealing device is configured for sealing off the opening 152 substantially vacuum-tight. As an example, the sealing device is attached to the evaporation source 1000, as will be explained with reference to FIGS. 4A to 4C and FIG. 5. When the opening 152 is closed or sealed by the sealing device, the maintenance vacuum chamber 150 can be vented and opened for maintenance of the evaporation source 1000 without breaking the vacuum in the processing vacuum chamber 110.

In some examples, the opening 152 and the sealing device can be included in a valve connecting the processing vacuum chamber 110 and the maintenance vacuum chamber 150. The valve can be configured for opening and closing the vacuum seal between the processing vacuum chamber 110 and the maintenance vacuum chamber 150. The evaporation source 1000 can be transferred to the maintenance vacuum chamber 150 while the valve is in an open state. Thereafter, the valve can be closed to provide the vacuum seal between the processing vacuum chamber 110 and the maintenance vacuum chamber 150. If the valve is closed, the maintenance vacuum chamber 150 can be vented and opened for maintenance of the evaporation source 1000 without breaking the vacuum in the processing vacuum chamber 110.

In some implementations, further tracks are provided for supporting the mask frames 131 and/or the masks 132. According to some embodiments, which can be combined with other embodiments described herein, the processing apparatus 100 can include four tracks within the processing vacuum chamber 110. In order to move one of the masks 132 out of the processing vacuum chamber 110, for example for cleaning of the mask 132, the mask frame 131 and the mask 132 can be moved onto transportation tracks of the substrate 121. The respective mask frame 131 can then exit or enter the processing vacuum chamber 110 on the transportation track for the substrate 121. Even though it would be possible to provide a separate transportation track into and out of the processing vacuum chamber 110 for the mask frames 131, the costs of ownership of a processing apparatus 200 can be reduced if only two tracks, i.e. transportation tracks for the substrate 121, extend into and out of the processing vacuum chamber 110 and, in addition, the mask frames 131 can be moved onto a respective one of the transportation tracks for the substrate 121 by an appropriate actuator or robot.

According to some embodiments, which can be combined with other embodiments described herein, the substrate 121 can be supported by a substrate support 126 connected to an alignment unit 112. The alignment unit 112 can adjust the position of the substrate 121 with respect to the mask 132. FIGS. 1A to 1C illustrate an embodiment where the substrate support 126 is connected to the alignment unit 112. The substrate 121 can be moved relative to the mask 132 in order to provide for an alignment between the substrate 121 and the mask 132 during deposition of the organic material. According to a further embodiment, which can be combined with other embodiments described herein, alternatively or additionally the mask 132 and/or the mask frame 131 holding the mask 132 can be connected to the alignment unit 112. Either the mask 132 can be positioned relative to the substrate 121 or the mask 132 and the substrate 121 can both be positioned relative to each other. The alignment unit 112 is configured for adjusting the position between a substrate 121 and the mask 132 relative to each other and allows for an alignment of the masking during the deposition process, being beneficial for high quality or OLED display manufacturing.

Examples of an alignment of the mask 132 and the substrate 121 relative to each other include the alignment unit 112 configured for a relative alignment in at least two directions defining a plane, which plane is substantially parallel to the plane of the substrate 121 and the plane of the mask 132. For example, an alignment can at least be conducted in an x-direction and a y-direction, i.e., two Cartesian directions defining the above-described parallel plane. As an example, the mask 132 and the substrate 121 can be essentially parallel to each other. The alignment can further be conducted in a direction substantially perpendicular to the plane of the substrate 121 and the plane of the mask 132. The alignment unit 112 can be configured at least for an X-Y-alignment, and specifically for an X-Y-Z-alignment of the mask 132 and the substrate 121 relative to each other. As an example, the substrate 121 can be aligned in the x-direction, y-direction and z-direction to the mask 132, and the mask 132 can be held stationary in the processing vacuum chamber 110.

As shown in FIGS. 1A to 1C, the at least two tracks 220, e.g. a linear guide, provide a direction of the translational movement of the evaporation source 1000 within the processing vacuum chamber 110. On both sides of the evaporation source 1000 a respective mask 132 is provided. The masks 132 can extend essentially parallel to the direction of the translational movement. Further, the substrates 121 at the opposing sides of the evaporation source 1000 can also extend essentially parallel to the direction of the translational movement. According to some embodiments, the substrate 121 can be moved into the processing vacuum chamber 110 and out of the processing vacuum chamber 110 through valve 105. The processing apparatus 100 can include a respective transportation track for transportation of each of the substrates 121. For example, the transportation track can extend parallel to the substrate position shown in FIGS. 1A to 1C and into and out of the processing vacuum chamber 110.

The processing apparatus 100 facilitates servicing and/or refilling of evaporation source 1000, and can reduce a downtime of the processing apparatus. By attaching the maintenance vacuum chamber 150 to the processing vacuum chamber 110 and transferring the evaporation source 1000 from the processing vacuum chamber 110 to the maintenance vacuum chamber 150, the maintenance vacuum chamber 150 can be vented independently from the processing vacuum chamber 110. The evaporation source 1000 can be exchanged or serviced, e.g., after it is exhausted, without venting the vacuum system of the processing apparatus 100 and/or without stopping production.

FIG. 2 shows a schematic top view of a processing apparatus 200 for processing devices, particularly devices including organic materials therein, according to further embodiments described herein.

The processing apparatus 200 of FIG. 2 is similar to the processing apparatus 100 described above with reference to FIGS. 1A to C and only the differences are described in the following.

In the processing apparatus 200, the evaporation crucible 1004 and the distribution pipe 1006 of the evaporation source 1000 are transferred from the processing vacuum chamber 110 to the maintenance vacuum chamber 150 and from the maintenance vacuum chamber 150 to the processing vacuum chamber 110, wherein the support 1002 for the distribution pipe 1006 is not transferred from the processing vacuum chamber 110 to the maintenance vacuum chamber 150 and from the maintenance vacuum chamber 150 to the processing vacuum chamber 110. In other words, the support 1002 for the distribution pipe 1006 remains in the processing vacuum chamber 110, while the evaporation crucible 1004 and the distribution pipe 1006 of the evaporation source 1000 are transferred.

According to some embodiments, which can be combined with other embodiments described herein, the processing apparatus 200 includes a transfer device (not shown) configured for transferring the evaporation source 1000 from the processing vacuum chamber 110 to the maintenance vacuum chamber 150 and from the maintenance vacuum chamber 150 to the processing vacuum chamber 110. The transfer device can include a displacement device, such as an actuator, a drive, a linear drive, or an arm, connectable to the evaporation source 1000 for performing the transfer. The transfer device can additionally or alternatively be provided by a robot, e.g. with at least two moving directions and which can be located in the maintenance module.

By leaving the support 1002 in the processing vacuum chamber 110, portions of the evaporation source 1000 can be transferred to the maintenance vacuum chamber 150 which are to be serviced and/or exchanged, wherein portions of the evaporation source 1000 remain in the processing vacuum chamber 110 which are not to be serviced and/or exchanged. This allows for minimizing an effort for performing the transfer.

FIGS. 3A and 3B show schematic top views of a processing apparatus 300 for processing devices, particularly devices including organic materials therein, according to still further embodiments described herein.

The processing apparatus 300 of FIGS. 3A and 3B is similar to the processing apparatuses described above with reference to FIGS. 1A to C and 2, and only the differences are described in the following.

According to some embodiments, which can be combined with other embodiments described herein, the processing apparatus 300 includes the evaporation source support system disposed in the processing vacuum chamber 110 and having the at least two tracks 220, wherein the at least two tracks 220 of the evaporation source support system are configured for the translational movement of the evaporation source 1000 at least within the processing vacuum chamber 110.

According to some embodiments, which can be combined with other embodiments described herein, each one of the at least two tracks 220 includes a first track section 221 and a second track section 222, and wherein the first track section 221 and the second track section 222 are separable. In some implementations, the first track section 221 is configured to be transferable from the processing vacuum chamber 110 to the maintenance vacuum chamber 150 and from the maintenance vacuum chamber 150 to the processing vacuum chamber 110, e.g., together with the evaporation source 1000.

In some implementations, the evaporation crucible 1004 and the distribution pipe 1006 are transferred together with the first track sections 221. In other implementations, the evaporation crucible 1004, the distribution pipe 1006 and the support 1002 for the distribution pipe 1006 are transferred together with the first track sections 221.

The evaporation source 1000 is provided in the processing vacuum chamber 110 on the at least two tracks 220, e.g. a looped track or linear guide. The at least two tracks 220 are configured for the translational movement of the evaporation source 1000, in particularly during operation, such as a deposition process. According to some embodiments, which can be combined with other embodiments described herein, the first drive for the translational movement of the evaporation source 1000 can be provided at the least two tracks 220, in particular at the first track sections 221, in the evaporation source 1000, within the processing vacuum chamber 110, or a combination thereof.

According to some embodiments, the first drive configured for the translational movement of the evaporation source can be transferred together with the evaporation source 1000 from the processing vacuum chamber 110 to the maintenance vacuum chamber 150 and from the maintenance vacuum chamber 150 to the processing vacuum chamber 110. As an example, the first drive can be configured for moving or driving the evaporation source 1000 and the first track sections 221 from the processing vacuum chamber 110 to the maintenance vacuum chamber 150 and from the maintenance vacuum chamber 150 to the processing vacuum chamber 110. In some examples, no additional device has to be provided for the transfer of the evaporation source when the first drive used for the translational movement is also used for the transfer.

When transferring the first track section 221 together with the evaporation source 1000, the evaporation source 1000 has not to be decoupled from the evaporation source support system before the transfer from the processing vacuum chamber 110 to the maintenance vacuum chamber 150 takes place. Further, the evaporation source 1000 has not to be coupled to the evaporation source support system after the transfer from the maintenance vacuum chamber 150 to the processing vacuum chamber 110 has been performed, saving time and effort.

FIGS. 4A to 4C show schematic top views of a processing apparatus 400 for processing devices, particularly devices including organic materials therein, according to yet further embodiments described herein.

The processing apparatus 400 of FIGS. 4A to C is similar to the processing apparatuses described above and only the differences are described in the following.

According to some embodiments, which can be combined with other embodiments described herein, the connection of the maintenance vacuum chamber 150 and the processing vacuum chamber 110 includes an opening (indicated with reference numeral 152 in FIGS. 1 to 3), wherein the opening is configured for the transfer of the evaporation source 1000 from the processing vacuum chamber 110 to the maintenance vacuum chamber 150 and from the maintenance vacuum chamber 150 to the processing vacuum chamber 110.

In some embodiments, the processing apparatus 400 further includes a sealing device 410 configured for closing the opening. In particular, the sealing device 410 is configured for sealing off the opening substantially vacuum-tight. When the opening is closed or sealed by the sealing device 410, the maintenance vacuum chamber 150 can be vented and opened for maintenance of the evaporation source 1000 without breaking the vacuum in the processing vacuum chamber 110.

In some implementations, the sealing device 410 is attached to, or included in, the evaporation source 1000. As an example, the sealing device 410 can be mounted to a side of the evaporation source 1000, e.g., at the support 1002, in a substantially vertical orientation. In some embodiments, the sealing device 410 can be a plate that is configured for sealing or closing the opening between the processing vacuum chamber 110 and the maintenance vacuum chamber 150. Integrating the sealing device 410 with the evaporation source 1000 allows for saving space within the processing vacuum chamber 110 and/or the maintenance vacuum chamber 150.

According to some embodiments, the evaporation source 1000 is moveable with respect to the sealing device 410. As an example, at least the distribution pipe 1006 and the evaporation crucible 1004 are moveable with respect to the sealing device 410. In some implementations, the processing apparatus 400 can include a connection device 420 connecting the evaporation source 1000 and the sealing device 410. The connection device 420 can be configured to provide the moveable connection between the evaporation source 1000 and the sealing device 410. As an example, the sealing device 410 can include two or more arm portions connected by hinges, in order to provide the moveable connection.

In some implementations, the connection device 420 can be a translation device configured for moving the sealing device 410 with respect to the evaporation source 1000, and in particular with respect to the distribution pipe 1006 and the evaporation crucible 1004. For closing the opening, the evaporation source 1000 can be suitably positioned within the processing vacuum chamber 110 or the maintenance vacuum chamber 150, and the translation device can move the sealing device 410 with respect to the evaporation source 1000 towards the opening in order to close or seal the opening substantially vacuum-tight. The sealing device 410 is fixed with respect to the evaporation source 1000 during transfer from the maintenance vacuum chamber 150 to the processing vacuum chamber 110 and vice versa.

According to some embodiments, which can be combined with other embodiments described herein, the processing apparatus 400 includes a rotatable device 430 provided in the maintenance vacuum chamber 150. The rotatable device 430 can be configured for receiving the evaporation source 1000 and/or the first track sections (indicated with reference numeral 221 in FIGS. 3A and 3B). As an example, the rotatable device 430 can be a rotatable platform.

Referring to FIG. 4A, two evaporation sources 1000 are shown. A first evaporation source of the two evaporation sources is positioned in the processing vacuum chamber 110, and a second evaporation source of the two evaporation sources is positioned in the maintenance vacuum chamber 150. As an example, the second evaporation source of the two evaporation sources can be positioned on the rotatable device 430.

As shown in FIG. 4B, the first evaporation source, e.g., to be serviced or exchanged, can be transferred from the processing vacuum chamber 110 to the maintenance vacuum chamber 150, and in particular onto the rotatable device 430. As an example, the first evaporation source and the second evaporation source can be positioned back-to-back on the rotatable device 430, e.g., with their sealing devices being oriented towards each other. In other words, both sealing devices can be positioned or sandwiched between the first evaporation source and the second evaporation source.

When both evaporations sources, i.e., the first evaporation source and the second evaporation source, are positioned on the rotatable device 430, the rotatable device 430 is rotated, e.g., about 180 degrees, so that the first evaporation source and the second evaporation source exchange positions. In FIG. 4B, the rotation is indicated with arrows. Then, the second evaporation source can be transferred into the processing vacuum chamber 110 and the opening connecting the processing vacuum chamber 110 and the maintenance vacuum chamber 150 can be sealed, e.g., by the sealing device 410 of the second evaporation source. The maintenance vacuum chamber 150 can be vented for servicing or removal of the first evaporation source. This allows an exchange of evaporation sources without having to break the vacuum in the processing vacuum chamber 110.

FIG. 5 shows a schematic top view of a processing apparatus 500 for processing devices, particularly devices including organic materials therein, according to embodiments described herein.

The processing apparatus 500 of FIG. 5 is similar to the processing apparatus described above with reference to FIGS. 4A to C, and only the differences are described in the following.

According to some embodiments, which can be combined with other embodiments described herein, the processing apparatus 500 includes the evaporation source support system disposed in the processing vacuum chamber 110 and having the at least two tracks 220, wherein the at least two tracks 220 of the evaporation source support system are configured for the movement of the evaporation source 1000 at least within the processing vacuum chamber 110. Each one of the at least two tracks 220 includes the first track section 221 and the second track section 222, wherein the first track section 221 and the second track section 222 are separable. In some implementations, the first track section 221 is configured to be transferable from the processing vacuum chamber 110 to the maintenance vacuum chamber 150 and from the maintenance vacuum chamber 150 to the processing vacuum chamber 110 together with the evaporation source 1000.

According to some embodiments, which can be combined with other embodiments described herein, the connection of the maintenance vacuum chamber 150 and the processing vacuum chamber 110 includes the opening configured for the transfer of the evaporation source 1000 from the processing vacuum chamber 110 to the maintenance vacuum chamber 150 and from the maintenance vacuum chamber 150 to the processing vacuum chamber 110.

In some embodiments, the processing apparatus 500 further includes the sealing device 510 configured for closing the opening. In some implementations, the sealing device 510 is attached to the evaporation source 1000. The sealing device 510 can be a plate that is configured for sealing the opening between the processing vacuum chamber 110 and the maintenance vacuum chamber 150.

According to some embodiments, the evaporation source 1000 is moveable with respect to the sealing device 510. As an example, the processing apparatus 500 can include a connection device 520 connecting the evaporation source 1000 and the sealing device 510. As an example, the connection device 520 is configured for guiding the translational movement of the sealing device 510 with respect to the evaporation source 1000. Additionally or alternatively, the connection device 520 can provide or accommodate a media supply for the evaporation source 1000. As an example, the connection device 520 can be an arm, in particular a passive arm. In some embodiments, at least a portion of the connection device 520 provides an atmospheric environment to prevent any particle impact on the media supply. As an example, the atmospheric environment can be provided inside the connection device 520, and can in particular be provided inside of the arm.

In some implementations, the arm can include two or more arm portions connected by respective hinges to allow the relative movement between the evaporation source 1000 and the sealing device 510. As an example, the connection device 520 includes a first arm 532 and a second arm 534. The first arm 532 has a first end portion connected to the evaporation source 1000 and a second end portion connected to a third end portion of the second arm 534 via a hinge 536. The second arm 534 has a fourth end portion connected to the processing vacuum chamber 110 and/or the maintenance vacuum chamber 150.

According to some embodiments, which can be combined with other embodiments described herein, the processing apparatus 500 includes a rotatable device 530 provided within the maintenance vacuum chamber 150. The rotatable device 530 can be configured for receiving the evaporation source 1000 and/or the first track sections 221. As an example, the rotatable device 530 can be a rotatable platform. In some embodiments, the processing apparatus 500 includes a drive configured for driving or rotating the rotatable device 530. The drive may be connected to the rotatable device 530 via a shaft, e.g., a hollow shaft.

According to some embodiments, the rotatable device 530 is configured for supporting two or more evaporation sources. As an example, a first evaporation source, e.g., to be serviced or exchanged, can be transferred from the processing vacuum chamber 110 to the maintenance vacuum chamber 150, and in particular onto the rotatable device 530. A second evaporation source, e.g., a serviced or new one, can also be provided on the rotatable device 530. When both evaporation sources, i.e., the first evaporation source and the second evaporation source, are positioned on the rotatable device 530, the rotatable device 530 is rotated, e.g., about 180 degrees, so that the first evaporation source and the second evaporation source exchange positions. Then, the second evaporation source can be transferred into the processing vacuum chamber 110 and the opening connecting the processing vacuum chamber 110 and the maintenance vacuum chamber 150 can be sealed, e.g., by the sealing device 510 of the second evaporation source. The maintenance vacuum chamber 150 can be vented for servicing or removal of the first evaporation source, e.g., by opening a door 154 of the maintenance vacuum chamber 150. This allows an exchange of evaporation sources without having to break the vacuum in the processing vacuum chamber 110.

According to some embodiments, which can be combined with other embodiments described herein, the evaporation source 1000 includes an actuator, for example a torque motor, an electric rotor or a pneumatic rotor. The actuator can provide a torque via a vacuum rotation feed-through, for example a ferrofluid sealed rotation feed-through. The actuator is configured to rotate at least the distribution pipes 1006 around an axis, which is essentially vertical. The evaporation source 1000 includes the support 1002, which can, for example, house the actuator and the feed-through. According to some embodiments, which can be combined with other embodiments described herein, the evaporation source 1000 further includes an evaporator control housing. The evaporator control housing can be an atmospheric box, i.e. a box configured to maintain atmospheric pressure therein even when the processing vacuum chamber 110 is evacuated to a technical vacuum. For example, at least one element selected from the group consisting of: a switch, a valve, a controller, a cooling unit and a cooling control unit can be provided in the evaporator control housing. The support 1002 further supports the evaporation crucibles 1004 and the distribution pipes 1006.

According to some embodiments, which can be combined with other embodiments described herein, the processing apparatus 500 can include a supply passage, e.g., a supply line. The supply passage can be configured for supplying the evaporation source 1000, e.g., with electrical connections and/or media such as fluids (e.g., water) and/or gases. The supply passage may be configured for guiding one or more lines and/or cables therethrough, such as water supply lines, gas supply lines and/or electric cables. In some implementations, the supply passage has an atmospheric environment, i.e. the supply passage can be configured to maintain atmospheric pressure therein even when a surrounding such as the processing vacuum chamber 110 and/or the maintenance vacuum chamber 150 is evacuated to a technical vacuum. As an example, the supply passage can include at least a part of the connection device 520.

In some implementations, the supply passage extends from the evaporation source 1000 to a feed through provided between the processing vacuum chamber 110 and the maintenance vacuum chamber 150. As an example, the feed through can be provided in or at the sealing device 510 or a wall portion separating the processing vacuum chamber 110 and the maintenance vacuum chamber 150. According to some embodiments, the supply passage extends from the evaporation source 1000 to the feed through via at least one of the evaporator control housings (that can be the atmospheric box) and the connection device 520.

In some embodiments, the supply passage extends from an outside of the maintenance vacuum chamber 150 into the maintenance vacuum chamber, e.g., through a hollow shaft of the drive of the rotatable device 530, and into an intermediate space or bottom of the rotatable device 530. The supply passage can further extend from the intermediate space or bottom of the rotatable device 530, e.g., via a line such as corrugated hose, to an atmospheric box provided in or at the sealing device 510. The atmospheric box can be included in a “back pack” attached to the sealing device 510. The above-mentioned feed through can be provided in or at the atmospheric box provided in or at the sealing device 510. As an example, the atmospheric box provided in or at the sealing device 510 can be configured as the feed through. The supply passage can further extend from the atmospheric box provided in or at the sealing device 510 to the evaporator control housing via the connection device 520. The supply passage can then extend from the evaporator control housing to the evaporation source 1000, e.g., to an atmospheric box of the evaporation source 1000, through a hollow shaft of the actuator configured to rotate at least the distribution pipes 1006.

According to one embodiment, a processing apparatus for processing devices, particularly devices including organic materials therein, is provided. The processing apparatus includes a processing vacuum chamber and at least one evaporation source for a material, wherein the at least one evaporation source includes at least one evaporation crucible, wherein the at least one evaporation crucible is configured to evaporate the material and at least one distribution pipe with one or more outlets, and wherein the at least one distribution pipe is in fluid communication with the at least one evaporation crucible. The processing apparatus has an atmospheric box in or at the evaporation source, which is configured for media supply to the evaporation source. The processing apparatus further includes a connection device, which is configured for media supply from the atmospheric box to an atmosphere outside of the processing apparatus. For example, the processing apparatus further includes a maintenance vacuum chamber connected with the processing vacuum chamber. The connection device can provide an atmospheric path from the atmospheric box in the processing vacuum chamber to the maintenance vacuum chamber, e.g., to a further atmospheric box in the maintenance vacuum chamber. According to yet further optional modifications, a further atmospheric path from the further atmospheric box to an outside of the maintenance vacuum chamber, i.e. outside of the processing apparatus, can be provided. According to some embodiments, further variations, features, aspects, and details described in the present disclosure, can be combined with the processing apparatus including the atmospheric box.

According to an aspect of the present disclosure, the processing apparatus includes a processing vacuum chamber; at least one evaporation source for organic material or non-organic material, e.g. Ag, Mg, or the like, wherein the at least one evaporation source includes at least one evaporation crucible, wherein the at least one evaporation crucible is configured to evaporate the organic material or the non-organic material, e.g. Ag, Mg or the like, and at least one distribution pipe with one or more outlets, wherein the at least one distribution pipe is in fluid communication with the at least one evaporation crucible; and a maintenance vacuum chamber connected with the processing vacuum chamber, wherein the at least one evaporation source can be transferred from the processing vacuum chamber to the maintenance vacuum chamber and from the maintenance vacuum chamber to the processing vacuum chamber, wherein the connection of the maintenance vacuum chamber and the processing vacuum chamber includes an opening, wherein the opening is configured for the transfer of the at least one evaporation source from the processing vacuum chamber to the maintenance vacuum chamber and from the maintenance vacuum chamber to the processing vacuum chamber, wherein the processing apparatus further includes a sealing device configured for closing the opening, and wherein the sealing device is attached to the at least one evaporation source.

FIGS. 6A to C show portions of an evaporation source 1000 according to embodiments described herein. The evaporation source 1000 can include a distribution pipe 1006 and an evaporation crucible 1004 as shown in FIG. 6A. For example, the distribution pipe 1006 can be an elongated cube with a first heating unit 615. The evaporation crucible 1004 can be a reservoir for the organic material to be evaporated with a second heating unit 625. According to some embodiments, which can be combined with other embodiments described herein, the distribution pipe 1006 provides a line source. For example, a plurality of openings and/or outlets, such as nozzles, is arranged along at least one line. According to an alternative embodiment, one elongated opening extending along the at least one line can be provided. For example, the elongated opening can be a slit. According to some embodiments, which can be combined with other embodiments described herein, the line extends essentially vertically. For example, the length of the distribution pipe 1006 corresponds at least to the height of the substrate to be deposited in the processing apparatus of the present embodiments. In some cases, the length of the distribution pipe 1006 can be longer than the height of the substrate to be deposited, at least by 10% or even 20%. A uniform deposition at the upper end of the substrate and/or the lower end of the substrate can be provided.

According to some embodiments, which can be combined with other embodiments described herein, the length of the distribution pipe 1006 can be 1.3 m or above, for example 2.5 m or above. According to one configuration, as shown in FIG. 2A, the evaporation crucible 1004 is provided at the lower end of the distribution pipe 1006. The organic material is evaporated in the evaporation crucible 1004. The vapor of organic material enters the distribution pipe 1006 at the bottom of the distribution pipe 1006 and is guided essentially sideways through the plurality of openings in the distribution pipe 1006, e.g. towards an essentially vertical substrate.

According to some embodiments, which can be combined with other embodiments described herein, the outlets (e.g. nozzles) are arranged to have a main evaporation direction to be horizontal +−20°. According to some specific embodiments, the evaporation direction can be oriented slightly upward, e.g. to be in a range from horizontal to 15° upward, such as 3° to 7° upward. The substrate can be slightly inclined to be substantially perpendicular to the evaporation direction and undesired particle generation can be reduced. For illustrative purposes, the evaporation crucible 1004 and the distribution pipe 1006 are shown without heat shields in FIG. 6A. As an example, the first heating unit 615 and the second heating unit 625 can be seen in the schematic perspective view shown in FIG. 6A.

FIG. 6B shows an enlarged schematic view of a portion of the evaporation source 1000, wherein the distribution pipe 1006 is connected to the evaporation crucible 1004. A flange unit 603 is provided, which is configured to provide a connection between the evaporation crucible 1004 and the distribution pipe 1006. As an example, the evaporation crucible 1004 and the distribution pipe 1006 are provided as separate units that can be separated and connected or assembled at the flange unit 603, e.g. for operation of the evaporation source.

The distribution pipe 1006 has an inner hollow space 610. The first heating unit 615 is provided to heat the distribution pipe 1006. As an example, the distribution pipe 1006 can be heated to a temperature such that the vapor of the organic material that is provided by the evaporation crucible 1004 does not condense at an inner portion of the wall of the distribution pipe 1006. Two or more heat shields 617 are provided around the tube of the distribution pipe 1006. The heat shields are configured to reflect heat energy provided by the first heating unit 615 back towards the hollow space 610. In view of this, an energy required to heat the distribution pipe 1006, i.e. the energy provided to the first heating unit 615, can be reduced because the heat shields 617 reduce heat losses. Further, heat transfer to other distribution pipes and/or to the mask or substrate can be reduced. According to some embodiments, which can be combined with other embodiments described herein, the two or more heat shields 617 can include two or more heat shield layers, e.g. five or more heat shield layers, such as ten heat shield layers.

In some examples, as shown in FIG. 6B, the two or more heat shields 617 include openings at positions of the opening or outlet 612 in the distribution pipe 1006. The enlarged view of the evaporation source shown in FIG. 6B shows four openings or outlets 612. The openings or outlets 612 can be provided along one or more lines that are essentially parallel to an axis of the distribution pipe 1006. As described herein, the distribution pipe 1006 can be provided as a linear distribution showerhead, for example, having a plurality of openings disposed therein. A showerhead as understood herein has an enclosure, hollow space, or pipe, in which the material can be provided or guided, for example from the evaporation crucible 1004. The showerhead can have a plurality of openings (or an elongated slit) such that the pressure within the showerhead is higher than outside of the showerhead. For example, the pressure within the showerhead can be at least one order of magnitude higher than that outside of the showerhead.

During operation, the distribution pipe 1006 is connected to the evaporation crucible 1004 at the flange unit 603. The evaporation crucible 1004 is configured to receive the organic material to be evaporated and to evaporate the organic material. FIG. 6B shows a cross-section through a housing of the evaporation crucible 1004. A refill opening is provided, for example at an upper portion of the evaporation crucible 1004, which can be closed using a plug 622, a lid, a cover or the like for closing the enclosure of evaporation crucible 1004.

A second heating unit 625, such as an outer heating unit, can be provided within the enclosure of the evaporation crucible 1004. The second heating unit 625 can extend at least along a portion of the wall of the evaporation crucible 1004. According to some embodiments, which can be combined with other embodiments described herein, one or more central heating elements 626 can be provided. FIG. 6B shows two central heating elements 626. The central heating elements 626 can include conductors 629 for providing electrical power to the central heating elements 626. According to some implementations, the evaporation crucible 1004 can further include a shield 627. The shield 627 can be configured to reflect heat energy, which is provided by the second heating unit 625 and, if present, the central heating elements 626, back into the enclosure of the evaporation crucible 1004. Efficient heating of the organic material within the evaporation crucible 1004 can be provided.

According to some embodiments, as exemplarily shown with respect to FIGS. 6A to 6B, the evaporation crucible 1004 is provided at a lower side of the distribution pipe 1006. According to yet further embodiments, which can be combined with other embodiments described herein, a vapor conduit 632 can be provided to the distribution pipe 1006 at a central portion of the distribution pipe 1006 or at another position between the lower end of the distribution pipe 1006 and the upper end of the distribution pipe 1006. FIG. 6C illustrates an example of the evaporation source having the distribution pipe 1006 and the vapor conduit 632 provided at the central portion of the distribution pipe 1006. Vapor of organic material is generated in the evaporation crucible 1004 and is guided through the vapor conduit 632 to the central portion of the distribution pipe 1006. The vapor exits the distribution pipe 1006 through the plurality of openings or outlets 612. The distribution pipe 1006 is supported by the support 1002 as described with respect to other embodiments described herein. According to yet further embodiments, which can be combined with other embodiments described herein, two or more vapor conduits 632 can be provided at different positions along the length of the distribution pipe 1006. As an example, the vapor conduits 632 can either be connected to one evaporation crucible 1004 or to several evaporation crucibles 1004. For example, each vapor conduit 632 can have a corresponding evaporation crucible 1004. Alternatively, the evaporation crucible 1004 can be in fluid communication with two or more vapor conduits 632, which are connected to the distribution pipe 1006.

The embodiments described herein can be utilized for evaporation on large area substrates. According to some embodiments, large area substrates may have a size of at least 0.67 m². Typically, the size can be about 0.67 m² (0.73×0.92 m−Gen 4.5) to about 8 m², more typically about 2 m² to about 9 m² or even up to 12 m². For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

FIG. 7 shows a flowchart of a method 700 for transferring an evaporation source from a processing vacuum chamber to a maintenance vacuum chamber or from the maintenance vacuum chamber to the processing vacuum chamber according to embodiments described herein.

According to an aspect of the present disclosure, the method 700 includes in block 710 moving an evaporation crucible and a distribution pipe of the evaporation source from the processing vacuum chamber to the maintenance vacuum chamber or from the maintenance vacuum chamber to the processing vacuum chamber through an opening provided between the processing vacuum chamber and the maintenance vacuum chamber.

According to some implementations, the method 700 further includes, in block 720, moving a first track section of two track sections of a track of an evaporation source support system disposed in the processing vacuum chamber together with the evaporation crucible and the distribution pipe of the evaporation source from the processing vacuum chamber to the maintenance vacuum chamber or from the maintenance vacuum chamber to the processing vacuum chamber through the opening; and/or sealing the opening by a sealing device attached to the evaporation source.

According to embodiments described herein, the method for transferring an evaporation source from a processing vacuum chamber to a maintenance vacuum chamber or from the maintenance vacuum chamber to the processing vacuum chamber can be conducted by means of computer programs, software, computer software products and the interrelated controllers, which can have a CPU, a memory, a user interface, and input and output means being in communication with the corresponding components of the apparatus for processing a large area substrate.

While the foregoing is directed to embodiments of the disclosure, other and further embodiments of the disclosure may be devised without departing from the basic scope thereof, and the scope thereof is determined by the claims that follow.

1. A processing apparatus for processing devices, comprising:
a processing vacuum chamber;
at least one evaporation source for a material, wherein the at least one evaporation source comprises:
at least one evaporation crucible, wherein the at least one evaporation crucible is configured to evaporate the material; and
at least one distribution pipe with one or more outlets, wherein the at least one distribution pipe is in fluid communication with the at least one evaporation crucible; and
a maintenance vacuum chamber connected with the processing vacuum chamber, wherein the at least one evaporation source can be transferred from the processing vacuum chamber to the maintenance vacuum chamber and from the maintenance vacuum chamber to the processing vacuum chamber.

2. The processing apparatus of claim 1, wherein the at least one evaporation source includes a support for the distribution pipe.

3. The processing apparatus of claim 2, wherein the support is connectable to a first drive or includes the first drive, wherein the first drive is configured for a translational movement of the evaporation source.

4. The processing apparatus of claim 2, wherein the evaporation crucible and the distribution pipe of the evaporation source can be transferred from the processing vacuum chamber to the maintenance vacuum chamber and from the maintenance vacuum chamber to the processing vacuum chamber, and wherein the support for the distribution pipe is not transferred from the processing vacuum chamber to the maintenance vacuum chamber and from the maintenance vacuum chamber to the processing vacuum chamber.

5. The processing apparatus of claim 1, wherein the connection of the maintenance vacuum chamber and the processing vacuum chamber includes an opening, wherein the opening is configured for the transfer of the evaporation source from the processing vacuum chamber to the maintenance vacuum chamber and from the maintenance vacuum chamber to the processing vacuum chamber.

6. The processing apparatus of claim 5, further including a sealing device configured for closing the opening.

7. The processing apparatus of claim 6, wherein the sealing device is attached to the at least one evaporation source.

8. The processing apparatus of claim 6, wherein at least the distribution pipe and the evaporation crucible are moveable with respect to the sealing device.

9. The processing apparatus of claim 1, further including an evaporation source support system disposed in the processing vacuum chamber and having at least two tracks, wherein the at least two tracks of the evaporation source support system are configured for a translational movement of the evaporation source at least within the processing vacuum chamber.

10. The processing apparatus of claim 9, wherein each one of the at least two tracks includes a first track section and a second track section, and wherein the first track section and the second track section are separable.

11. The processing apparatus of claim 10, wherein the first track section is configured to be transferable from the processing vacuum chamber to the maintenance vacuum chamber and from the maintenance vacuum chamber to the processing vacuum chamber together with the evaporation source.

12. The processing apparatus of claim 1, including a further vacuum chamber connected with the processing vacuum chamber via a valve, wherein the further vacuum chamber is configured for transport of a substrate into the processing vacuum chamber and out of the processing vacuum chamber.

13. A processing apparatus for processing devices including organic materials therein, comprising:
a processing vacuum chamber;
at least one evaporation source for a material, wherein the at least one evaporation source comprises:
at least one evaporation crucible, wherein the at least one evaporation crucible is configured to evaporate the material; and
at least one distribution pipe with one or more outlets, wherein the at least one distribution pipe is in fluid communication with the at least one evaporation crucible; and
a maintenance vacuum chamber connected with the processing vacuum chamber, wherein the at least one evaporation source can be transferred from the processing vacuum chamber to the maintenance vacuum chamber and from the maintenance vacuum chamber to the processing vacuum chamber, wherein the connection of the maintenance vacuum chamber and the processing vacuum chamber includes an opening, wherein the opening is configured for the transfer of the at least one evaporation source from the processing vacuum chamber to the maintenance vacuum chamber and from the maintenance vacuum chamber to the processing vacuum chamber, wherein the opening is closable by a sealing device, and wherein the sealing device is attached to the at least one evaporation source.

14. A method for transferring an evaporation source from a processing vacuum chamber to a maintenance vacuum chamber or from the maintenance vacuum chamber to the processing vacuum chamber, comprising:
moving an evaporation crucible and a distribution pipe of the evaporation source from the processing vacuum chamber to the maintenance vacuum chamber or from the maintenance vacuum chamber to the processing vacuum chamber through an opening provided between the processing vacuum chamber and the maintenance vacuum chamber.

15. The method of claim 14, further including:
moving a first track section of two track sections of a track of an evaporation source support system disposed in the processing vacuum chamber together with the evaporation crucible and the distribution pipe of the evaporation source from the processing vacuum chamber to the maintenance vacuum chamber or from the maintenance vacuum chamber to the processing vacuum chamber through the opening.

16. The processing apparatus of claim 3, wherein the first drive is configured for the translational movement of the evaporation source within the processing vacuum chamber.

17. The processing apparatus of claim 3, wherein the evaporation crucible and the distribution pipe of the evaporation source can be transferred from the processing vacuum chamber to the maintenance vacuum chamber and from the maintenance vacuum chamber to the processing vacuum chamber, and wherein the support for the distribution pipe is not transferred from the processing vacuum chamber to the maintenance vacuum chamber and from the maintenance vacuum chamber to the processing vacuum chamber.

18. The processing apparatus of claim 6, wherein the sealing device is configured for sealing the opening substantially vacuum-tight.

19. The processing apparatus of claim 1, wherein the processing devices include organic materials therein.

20. The method of claim 14, further including sealing the opening using a sealing device attached to the evaporation source.
